(19) United States
(12) Patent Application Publication
(10) Pub. No.: US 2026/0218046 A1
(43) Pub. Date: Jul. 30, 2026

(54) QUANTUM DOT COMPOSITION AND QUANTUM DOT LIGHT-EMITTING DEVICE

(71) Applicants: Guangdong Juhua Research Institute of Advanced Display, Guangzhou, Guangdong (CN); TCL Technology Group Corporation, Huizhou, Guangdong (CN)

(72) Inventors: Likuan ZHOU, Guangzhou, Guangdong (CN); Wenjun HOU, Guangzhou, Guangdong (CN); Weiran CAO, Guangzhou, Guangdong (CN)

(73) Assignees: Guangdong Juhua Research Institute of Advanced Display, Guangzhou, Guangdong (CN); TCL Technology Group Corporation, Huizhou, Guangdong (CN)

(21) Appl. No.: 19/144,494

(22) PCT Filed: Sep. 27, 2023
(86) PCT No.: PCT/CN2023/121992

§ 371 Date: Jun. 29, 2025

(30) Foreign Application Priority Data
Dec. 30, 2022 (CN) 202211738053.4

(51) Int. Cl. C09K 11/88; B82Y 20/00; B82Y 40/00; C09K 113/00; H10K 50/115; H10K 50/15; H10K 50/16; H10K 50/17; H10K 85/10; H10K 101/40

(52) U.S. Cl. CPC C09K 11/883; H10K 50/115; H10K 50/15; H10K 85/1135; H10K 85/115; B82Y 20/00; B82Y 40/00; C09K 2113/00; H10K 50/16; H10K 50/17; H10K 2101/40

(57) ABSTRACT

A quantum dot composition and a quantum dot light-emitting device are provided. The quantum dot composition includes a first quantum dot and a second quantum dot, the first quantum dot and the second quantum dot are both core-shell quantum dots. A ratio of a conduction band energy level of a core of the first quantum dot to that of the second quantum dot is 1:(0.9-1.1), and a ratio of a valence band energy level of the core of the first quantum dot to that of the second quantum dot is 1:(0.9-1.1). A conduction band energy level and a valence band energy level of an outermost shell of the second quantum dot are lower than those of the first quantum dot. The first quantum dot satisfies 0<ΔE_{VB,C1-S1}≤0.4 eV and ΔE_{CB,S1-C1}>0.4 eV, and the second quantum dot satisfies 0<ΔE_{CB,S2-C2}≤0.4 eV and ΔE_{VB,C2-S2}>0.4 eV.

This disclosure claims priority of the Chinese patent application with the Chinese Patent Application No. 202211738053.4, filed in the China National Intellectual Property Administration on Dec. 30, 2022, and entitled “QUANTUM DOT COMPOSITION AND QUANTUM DOT LIGHT-EMITTING DEVICE”, which is incorporated herein by reference in its entirety.

### TECHNICAL FIELD

The present disclosure relates to a field of quantum dot materials, and in particular to a quantum dot composition and a quantum dot light-emitting device.

### BACKGROUND

Quantum Dot Light-emitting Diodes (QLED) is expected to integrate the excellent light-emitting characteristics of colloidal quantum dot materials, such as nearly 100% light-emitting efficiency, high color purity (light-emitting peak width is less than 25 nm) and wavelength adjustable (from ultraviolet region to infrared region), and the chemical/photochemical stability possessed by inorganic crystals. In addition, QLED may also utilize large-area, high-capacity solution processing manufacturing method to realize flexible display with high color gamut, high contrast, fast response, high cost performance, and low energy consumption. Therefore, QLED technology is considered as an ideal solution for the next generation display technology.

In recent years, with the in-depth study of QLED performance, great progress has been made in the current efficiency and lifetime of the device. The external quantum efficiency (EQE) of the QLED device based on the cadmium-containing system is as high as 20.5%, and the working lifetime (LT95@1000 nit) is as long as 30000 hours, which may be comparable to the performance of commercial organic light-emitting diode. However, in the structure of the QLED device, due to the different energy level barriers between the light-emitting layer and the adjacent transport functional layer, the carriers injected into the light-emitting layer are unbalanced, which is one of the main factors limiting the high performance of QLED. In addition, in the QLED device structure, the quantum dot layer acts as a hole and electron recombination light-emitting area. Due to the unbalanced injection of holes and electrons, the exciton recombination region is offset to the hole layer/light-emitting layer interface, especially high exciton density may leads to the problems of poor photoelectric conversion efficiency and stability of the device, thereby affecting the commercial application of QLED technology.

Therefore, how to control the carrier balance in the light-emitting layer of the QLED device and effectively bind the excitons to avoid the low current efficiency and poor stability of the device caused by the offset of the exciton recombination region has become a problem in the QLED device.

### Technical Solution

In view of this, the present disclosure provides a quantum dot composition which is capable of adjusting carrier balance and binding excitons and a quantum dot light-emitting device.

The present disclosure provides a quantum dot composition including a first quantum dot and a second quantum dot, the first quantum dot and the second quantum dot are both core-shell quantum dots, a ratio of a conduction band energy level of a core of the first quantum dot to a conduction band energy level of a core of the second quantum dot is 1:(0.9-1.1), a ratio of a valence band energy level of the core of the first quantum dot to a valence band energy level of the core of the second quantum dot is 1:(0.9-1.1), a conduction band energy level of an outermost shell of the second quantum dot is lower than a conduction band energy level of an outermost shell of the first quantum dot, and a valence band energy level of the outermost shell of the second quantum dot is lower than a valence band energy level of the outermost shell of the first quantum dot;
where the first quantum dot satisfies 0<ΔE_{VB,C1-S1}≤0.4 eV and ΔE_{CB,S1-C1}>0.4 eV, and the second quantum dot satisfies 0<ΔE_{CB,S2-C2}≤0.4 eV and ΔE_{VB,C2-S2}>0.4 eV;
ΔE_{VB,C1-S1}=E_{VB,C1}−E_{VB,S1}, ΔE_{CB,S1-C1}=E_{CB,S1}−E_{CB,C1}, ΔE_{VB,C2-S2}=E_{VB,C2}−E_{VB,S2}, ΔE_{CB,S2-C2}=E_{CB,S2}−E_{CB,C2}, where C1, S1, C2, and S2 respectively represent the core and the shell of the first quantum dot and the core and the shell of the second quantum dot.

Optionally, a material of the core of the first quantum dot is the same as material of the core of the second quantum dot;
and/or, a difference between the full width half maximum of the emission spectra of the first quantum dot and a full width at half maximum of the emission spectra of the second quantum dot ranges from 0 nm to 5 nm;
and/or, a thickness of at least one shell of the first quantum dot and a thickness of at least one shell of the second quantum dot are less than or equal to 10 nm.

Optionally, the conduction band energy level of the core of the first quantum dot is not more than 10% different from the conduction band energy level of the core of the second quantum dot, and the valence band energy level of the core of the first quantum dot is not more than 10% different from the valence band energy level of the core of the second quantum dot.

Optionally, the ratio of the conduction band energy level of the core of the first quantum dot to the conduction band energy level of the core of the second quantum dot is 1:(0.95-1.05), and the ratio of the valence band energy level of the core of the first quantum dot to the valence band energy level of the core of the second quantum dot is 1:(0.95-1.05).

Optionally, the conduction band energy level of the core of the first quantum dot is the same as the conduction band energy level of the core of the second quantum dot, and the valence band energy level of the core of the first quantum dot is the same as the valence band energy level of the core of the second quantum dot.

Optionally, a material of the core and a material of the shell of the first quantum dot and the second quantum dot are independently selected from one or more of a group II-VI compound, a group IV-VI compound, a group III-V compound, and a group I-III-VI compound, the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the group I-III-VI compound is selected from one or more of CuInS₂, CuInSe₂, and AgInS₂; the perovskite semiconductor material is selected from a doped or undoped inorganic perovskite semiconductor or an organic-inorganic hybrid perovskite semiconductor, the inorganic perovskite semiconductor has a general structure of AMX₃, the organic-inorganic hybrid perovskite semiconductor has a structure general formula of BMX₃, where A is a Cs⁺ ion; B is an organic amine cation selected from CH₃ (CH₂)ₙ₋₂NH₃⁺ or [NH₃ (CH₂)ₙNH₃]²⁺, n≥2; M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; and X is a halide anion selected from one or more of Cl⁻, Br⁻, and I⁻.

The present disclosure further provides a quantum dot composition including a first quantum dot and a second quantum dot, the first quantum dot and the second quantum dot are both core-shell quantum dots, a ratio of a band gap width of a core of the first quantum dot to a band gap width of a core of the second quantum dot is 1:(0.9-1.1), a conduction band energy level of an outermost shell of the second quantum dot is lower than a conduction band energy level of an outermost shell of the first quantum dot, and a valence band energy level of the outermost shell of the second quantum dot is lower than a valence band energy level of the outermost shell of the first quantum dot;
where the first quantum dot satisfies 0<ΔE_{VB,C1-S1}≤0.4 eV and ΔE_{CB,S1-C1}>0.4 eV, and the second quantum dot satisfies 0<ΔE_{CB,S2-C2} and ΔE_{VB,C2-S2}>0.4 eV;
ΔE_{VB,C1-S1}=E_{VB,C1}−E_{VB,S1}, ΔE_{CB,S1-C1}=E_{CB,S1}−E_{CB,C1}, ΔE_{VB,C2-S2}=E_{VB,C2}−E_{VB,S2}, and ΔE_{CB,S2-C2}=E_{CB,S2}−E_{CB,C2}, where C1, S1, C2 and S2 respectively represent the core and the shell of the first quantum dot and the core and the shell of the second quantum dot.

Optionally, the ratio of the band gap width of the core of the first quantum dot to the band gap width of the core of the second quantum dot is 1:(0.95-1.05).

Optionally, a ratio of a conduction band energy level of the core of the first quantum dot to a conduction band energy level of the core of the second quantum dot is 1:(0.9-1.1), and a ratio of a valence band energy level of the core of the first quantum dot to a valence band energy level of the core of the second quantum dot is 1:(0.9-1.1).

Optionally, a ratio of a conduction band energy level of the core of the first quantum dot to a conduction band energy level of the core of the second quantum dot is 1:(0.95-1.05), and a ratio of a valence band energy level of the core of the first quantum dot to a valence band energy level of the core of the second quantum dot is 1:(0.95-1.05).

Optionally, the first quantum dot satisfies 1.5 eV>ΔE_{CB,S1-C1}, and the second quantum dot satisfies ΔE_{CB,S2-C2}≤0.4 eV and 1.5 eV>ΔE_{VB,C2-S2}.

Optionally, the first quantum dot is CdSe/ZnSe, the second quantum dot is CdSe/CdS, a conduction band energy level difference ΔE_{CB, shell-core} of the CdSe/ZnSe is 0.3 eV, a valence band energy level difference ΔE_{VB, core-shell} of the CdSe/ZnSe is 0.5 eV, a conduction band energy level difference ΔE_{CB, shell-core} of the CdSe/ZnSe is 1 eV, a valence band energy level difference ΔE_{VB, core-shell} of the CdSe/ZnSe is 0.1 eV, and a mass ratio of the CdSe/ZnSe to the CdSe/CdS is 1:1.

Optionally, the first quantum dot is CdZnSeS/CdZnS/ZnS, the second quantum dot is CdZnSeS/ZnSe/ZnS, a conduction band energy level difference ΔE_{CB, shell-core} of the CdZnSeS/CdZnS/ZnS is 0.2 eV, a valence band energy level difference ΔE_{VB, core-shell} of the CdZnSeS/CdZnS/ZnS is 0.7 eV, a conduction band energy level difference ΔE_{CB, shell-core} of the CdZnSeS/ZnSe/ZnS is 0.8 eV, a valence band energy level difference ΔE_{VB, core-shell} of the CdZnSeS/ZnSe/ZnS is 0.15 eV, and a mass ratio of the CdZnSeS/CdZnS/ZnS to the CdZnSeS/ZnSe/ZnS is 3:1.

The present disclosure further provides a quantum dot light-emitting device including an anode, a hole transport layer, a quantum dot light-emitting layer, and a cathode, which are sequentially stacked, and the quantum dot light-emitting layer includes the quantum dot composition above.

Optionally, a valence band energy level difference between the outermost shell of the first quantum dot and the hole transport layer satisfies ΔE_{HTL-S1}=E_{LUMO,HTL}−E_{VB,S1}<0.5 eV, and a conduction band energy level difference between the outermost shell of the second quantum dot and the electron transport layer satisfies ΔE_{EML-ETL}=E_{CB,S2}−E_{HOMO,ETL}<0.4 eV.

Optionally, the anode and the cathode are independently selected from a doped metal oxide particle electrode, a composite electrode, a graphene electrode, a carbon nanotube electrode, a metal element electrode, or an alloy electrode, the doped metal oxide particle electrode is selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide; the composite electrode is selected from AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, or ZnS/Al/ZnS; and the metal electrode is selected from one or more of Ag, Al, Cu, Au, Mo, Pt, Ca, and Ba;
and/or, the quantum dot light-emitting device further includes an electron transport layer, the electron transport layer is disposed between the quantum dot light-emitting layer and the cathode, and a material of the electron transport layer is selected from one or more of a metal oxide, a doped metal oxide, a group 2-6 semiconductor material, a group 3-5 semiconductor material, and a group 1-3-6 semiconductor material, the metal oxide is selected from one or more of ZnO, BaO, TiO₂, and SnO₂; a metal oxide of the doped metal oxide is selected from one or more of ZnO, TiO₂, and SnO₂, and a doping element of the doped metal oxide is selected from one or more of Al, Mg, Li, In, and Ga; the group 2-6 semiconductor material is selected from one or more of ZnS, ZnSe, and CdS; the group 3-5 semiconductor material is selected from one or more of InP and GaP; and the group 1-3-6 semiconductor material is selected from one or more of CuInS and CuGaS; and/or
a material of the hole transport layer is selected from one or more of 4,4′-N,N′-dicarbazolyl-biphenyl (CBP), N,N′-diphenyl-N,N′-bis(1-naphthyl)-1,1′-biphenyl-4,4″-diamine, N,N′-diphenyl-N,N′-bis(3-methylphenyl)-(1,1′-biphenyl)-4,4′-diamine, N,N′-bis(3-methylphenyl)-N,N′-bis(phenyl)-spiro(spiro-TPD), N,N′-di(4-(N,N′-diphenyl-amino)phenyl)-N,N′-diphenylbenzidine, 4,4′,4′-tris(N-carbazolyl)-triphenylamine, 4,4′,4′-tris(N-3-methylphenyl-N-phenylamino)triphenylamine, poly[(9,9′-dioctylfluorene-2,7-diyl)-co-(4,4′-(N-(4-sec-butyphenyl)diphenylamine))], poly(4-butylphenyl-diphenylamine) (poly-TPD), polyaniline, polypyrrole, poly(p) phenylenevinylene, poly(phenylenevinylene), poly[2-methoxy-5-(2-ethylhexyloxy)-1,4-phenylenevinylene] and poly[2-methoxy-5-(3′,7′-dimethyloctyloxy)-1,4-phenylenevinylene], copper phthalocyanine, aromatic tertiary amines, polynuclear aromatic tertiary amines, 4,4′-bis(N-carbazolyl)-1,1′-biphenyl compounds, N,N,N′,N′-tetraarylbiphenylamines, PEDOT:PSS and derivatives thereof, poly(N-vinylcarbazole) (PVK) and derivatives thereof, polymethacrylates and derivatives thereof, poly(9,9-octylfluorene) and derivatives thereof, poly(spirofluorene) and derivatives thereof, N,N′-di(naphthalen-1-yl)-N,N′-diphenylbenzidine, spiro-NPB, doped graphene, non-doped graphene, C60, doped or non-doped NiO, doped or non-doped MoO₃, doped or non-doped WO₃, doped or non-doped V₂O₅, doped or non-doped P-type gallium nitride, doped or non-doped CrO₃, and doped or non-doped CuO;
and/or, the quantum dot light-emitting device further includes a hole injection layer, the hole injection layer is disposed between the anode and the hole transport layer, and a material of the hole injection layer is selected from one or more of 2,3,6,7,10,11-hexacyano-1,4,5,8,9,12-hexaazatriphenylene, PEDOT, PEDOT:PSS, derivatives of PEDOT:PSS doped with s-MoO₃, 4,4′,4′-tris(N-3-methylphenyl-N-phenylamino)triphenylamine, tetracyanoquinodimethane, copper phthalocyanine, nickel oxide, molybdenum oxide, tungsten oxide, vanadium oxide, molybdenum sulfide, tungsten sulfide, and copper oxide.

The present disclosure further provides another quantum dot light-emitting device including an anode, a hole injection layer, a hole transport layer, a first quantum dot light-emitting layer, a second quantum dot light-emitting layer, and an electron transport layer, and a cathode, which are sequentially stacked; the first quantum dot light-emitting layer includes a first quantum dot, the second quantum dot light-emitting layer includes a second quantum dot, the first quantum dot and the second quantum dot are both core-shell quantum dots, a ratio of a conduction band energy level of a core of the first quantum dot to a conduction band energy level of a core of the second quantum dot is 1:(0.9-1.1), a ratio of a valence band energy level of the core of the first quantum dot to a valence band energy level of the core of the second quantum dot is 1:(0.9-1.1), a conduction band energy level of an outermost shell of the second quantum dot is lower than a conduction band energy level of an outermost shell of the first quantum dot, and a valence band energy level of the outermost shell of the second quantum dot is lower than a valence band energy level of the outermost shell of the first quantum dot;
the first quantum dot satisfies 0<ΔE_{VB,C1-S1}≤0.4 eV and ΔE_{CB,S1-C1}>0.4 eV, and the second quantum dot satisfies 0<ΔE_{CB,S2-C2}≤0.4 eV and ΔE_{VB,C2-S2}>0.4 eV, where ΔE_{VB,C1-S1}=E_{VB,C1}−E_{VB,S1}, ΔE_{CB,S1-C1}=E_{CB,S1}−E_{CB,C1}, ΔE_{VB,C2-S2}=E_{VB,C2}−E_{VB,S2}, and ΔE_{CB,S2-C2}=E_{CB,S2}−E_{CB,C2}.

Optionally, a valence band energy level difference between the outermost shell of the first quantum dot and the hole transport layer satisfies ΔE_{HTL-S1}=E_{LUMO,HTL}−E_{VB,S1}<0.5 eV, and a conduction band energy level difference between the outermost shell of the second quantum dot and the electron transport layer satisfies:

$$Δ {E}_{EML - ETL} = {E}_{CB , S 2} - {E}_{HOMO , ETL} < 0.4 eV .$$

### BRIEF DESCRIPTION OF DRAWINGS

In order to more clearly illustrate the technical solutions in the present disclosure, the following will briefly introduce the drawings required in the embodiments. Obviously, the drawings in the following description merely represent some of the embodiments of the present disclosure, and other drawings may be obtained by those skilled in the art without creative efforts.

FIG. 1 is a schematic diagram of an energy level structure of a quantum dot composition according to an embodiment of the present disclosure.

FIG. 2 is a schematic diagram of an energy level structure of a quantum dot composition according to another embodiment of the present disclosure.

FIG. 3 is a schematic diagram of a structure of a quantum dot light-emitting device according to an embodiment of the present disclosure.

FIG. 4 is a schematic diagram of an energy level structure of the quantum dot light-emitting device in FIG. 3.

FIG. 5 is a schematic diagram of a structure of a quantum dot light-emitting device according to another embodiment of the present disclosure.

### EMBODIMENTS OF THE PRESENT DISCLOSURE

The technical solutions in the present disclosure will be described clearly and completely below in combination with the drawings in the embodiments of the present disclosure. Obviously, the described embodiments are only part of the embodiments of the present disclosure, rather than all the embodiments. Based on the embodiments in the present disclosure, all the other embodiments obtained by those skilled in the art without creative work are within the protection scope of the present disclosure.

In the present disclosure, unless specifically stated and defined otherwise, a first feature “on” or “under” a second feature may include that the first feature and the second feature are directly connected, or that the first feature and the second feature are not directly connected, but are connected through another feature between them. Moreover, a first feature “on”, “above” or “on top of” a second feature include that the first feature is directly above or obliquely above the second feature, or only means that the first feature is higher than the second feature in horizontal height. A first feature “under”, “below” or “underneath” a second feature include that the first feature is directly below or obliquely below the second feature, or only means that the first feature is lower than the second feature in horizontal height. In addition, the terms “first” and “second” are only used for descriptive purposes, and may not be understood as indicating or implying relative importance or implicitly indicating the number of the indicated technical features. Therefore, the features defined with “first” and “second” may explicitly or implicitly include one or more features.

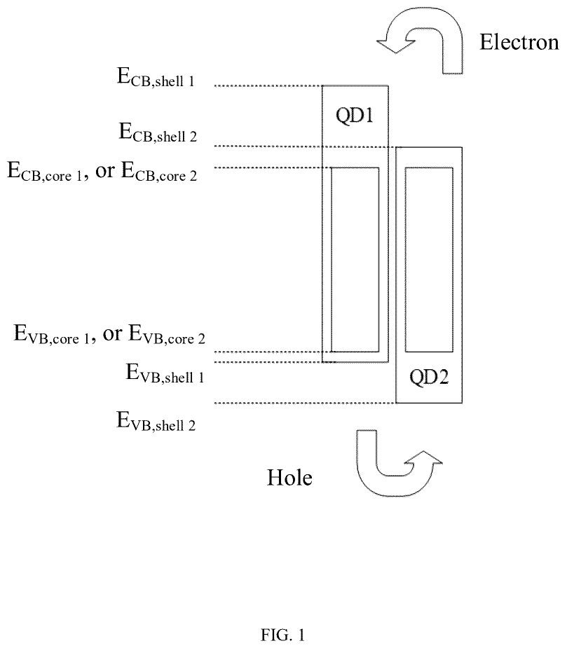

Referring to FIG. 1, an embodiment of the present disclosure provides a quantum dot composition including a first quantum dot QD1 and a second quantum dot QD2. The first quantum dot QD1 and the second quantum dot QD2 are both core-shell quantum dots. A ratio of a conduction band energy level of a core of the first quantum dot Q1 to a conduction band energy level of a core of the second quantum dot Q2 is 1:(0.9-1.1), and a ratio of the valence band energy level of the core of the first quantum dot Q1 to the valence band energy level of the core of the second quantum dot Q2 is 1:(0.9-1.1). A conduction band energy level of an outermost shell of the second quantum dot QD2 is lower than a conduction band energy level of an outermost shell of the first quantum dot QD1, and a valence band energy level of the outermost shell of the second quantum dot QD2 is lower than a valence band energy level of the outermost shell of the first quantum dot QD1. The first quantum dot QD1 satisfies 0<ΔE_{VB,C1-S1}≤0.4 eV and ΔE_{CB,S1-C1}>0.4 eV, and the second quantum dot QD2 satisfies 0<ΔE_{CB,S2-C2}≤0.4 eV and ΔE_{VB,C2-S2}>0.4 eV, where ΔE_{VB,C1-S1}=E_{VB,C1}−E_{VB,S1}, ΔE_{CB,S1-C1}=E_{CB,S1}−E_{CB,C1}, ΔE_{VB,C2-S2}=E_{VB,C2}−E_{VB,S2}, and ΔE_{CB,S2-C2}=E_{CB,S2}−E_{CB,C2}. C1 (Core 1), S1 (Shell 1), C2 (Core 2), and S2 (Shell 2) respectively represent the core and the shell of the first quantum dot and the core and the shell of the second quantum dot.

It should be noted that the core-shell quantum dot may include one shell, or two or more shells. Since the energy level structure of the core-shell quantum dot of the present disclosure is type I structure, when the core-shell quantum dot includes two or more shells, the valence band energy levels gradually becomes higher from the core to the first shell to the nth shell (n is greater than 1), and the conduction band energy levels gradually becomes lower from the core to the first shell to the nth shell (n is greater than 1). The valence band energy level in the above condition refers to the valence band energy level of the outermost shell of all shells, and the conduction band energy level refers to the conduction band energy level of the outermost shell of all shells.

The luminescence wavelength of the core-shell quantum dot is mainly determined by the core, the part affecting the luminescence in the core-shell quantum dot is the core, and the shell plays a passivation protection role. According to the formula Eg=1240/λ, where Eg is the band gap width of the core of the quantum dot, and λ is the luminescence wavelength of the quantum dot. The band gap width Eg between the conduction band and the valence band determines the luminescence wavelength λ, and the same band gap width ensures the same or similar luminescence wavelength, so that stray light is not emitted. In this embodiment, the conduction band energy level of the core of the first quantum dot QD1 is not more than 10% different from the conduction band energy level of the core of the second quantum dot QD2, and the valence band energy level of the core of the first quantum dot QD1 is not more than 10% different from the valence band energy level of the core of the second quantum dot QD2, so that the band gap widths of the cores of the first quantum dot QD1 and the second quantum dot QD2 are close, and light with similar wavelengths may be emitted. Optionally, the ratio of the conduction band energy level of the core of the first quantum dot Q1 to the conduction band energy level of the core of the second quantum dot Q2 is 1:(0.95-1.05), and the ratio of the valence band energy level of the core of the first quantum dot Q1 to the valence band energy level of the core of the second quantum dot Q2 is 1:(0.95-1.05). Optionally, the conduction band energy level of the core of the first quantum dot QD1 is the same as the conduction band energy level of the core of the second quantum dot QD2, and the valence band energy level of the core of the first quantum dot QD1 is the same as the valence band energy level of the core of the second quantum dot QD2.

It should be noted that even if the cores synthesized in the same batch, there may have errors between the conduction band energy level and the valence band energy level, or may have errors between the cores synthesized in different batches by the same method. In other embodiments of the present disclosure, in the case where the band gap widths are close or the same, the conduction band energy level and the valence band energy level of the cores of the first quantum dot QD1 and the second quantum dot QD2 may also differ greatly, for example, by more than 10%. Such embodiments will be discussed later.

The conduction band energy level and the valence band energy level of the outermost shell of the second quantum dot QD2 are both lower than the conduction band energy level of the outermost shell of the first quantum dot QD1. That is, the quantum dot composition includes the first quantum dot QD1 with a shallow valence band energy level and the second quantum dot QD2 with a deep conduction band energy level. It should be noted that a large absolute value of the energy level indicates a deep energy level, and a small absolute value of the energy level indicates a shallow energy level. A shallow valence band indicates that the valence band energy level is relatively high, and the valence band energy level is below zero relative to the vacuum energy level, thereby the shallower the valence band energy level is, the higher the valence band energy level is. Similarly, a deep conduction band energy level indicates that the conduction band energy level is relatively low. Similarly, a shallow valence band energy level refers to a high valence band top, and a deep conduction band energy level refers to a low conduction band bottom. The quantum dot composition of the present disclosure may be used in a QLED device as a quantum dot light-emitting layer material. The energy level of the first quantum dot QD1 with a shallow valence band may be matched with a hole transport layer in the quantum dot light-emitting device, and is used for hole injection. Increasing the proportion of the first quantum dot QD1 in the quantum dot composition is conducive to the improvement of the hole injection level. The energy level of the second quantum dot QD2 may be matched with an electron transport layer in the quantum dot light-emitting device, and is used for electron injection. Increasing the proportion of the second quantum dot QD2 in the quantum dot composition is conducive to the improvement of the electron injection level. Mixing quantum dots with different shell structures in a certain proportion may obtain a mixed quantum dot light-emitting layer energy level structure with a smaller energy level barrier to the hole transport layer and the electron transport layer, which is more conducive to the regulation and control of the carrier balance injected into the quantum dot light-emitting layer, and higher quantum dot light-emitting efficiency may be obtained.

For the core-shell type quantum dot material, when carriers are injected, the carriers are injected into the outer shell first, and then injected into the core through the shell. For the first quantum dot QD1, 0<ΔE_{VB,C1-S1} and ΔE_{CB,S1-C1}>0.4 eV, that is, the valence band energy level of the core of the first quantum dot QD1 is higher than the valence band energy level of the outermost shell, and the conduction band energy level of the core is lower than the conduction band energy level of the outermost shell. The first quantum dot QD1 is a type I quantum dot, and has good confinement capability. It is generally believed that under the condition of Schottky contact (the energy level barrier is greater than 0.4 eV), electrons and holes have a certain confinement effect. For the first quantum dot QD1, ΔE_{VB,C1-S1}≤0.4 eV, so the valence band energy level barrier between the outermost shell and the core of the first quantum dot QD1 is lower than the Schottky barrier, which is conducive to the injection of holes from the shell of the first quantum dot QD1 to the core of the first quantum dot QD1. ΔE_{CB,S1-C1}>0.4 eV, the conduction band energy level barrier between the outermost shell and the core of the first quantum dot QD1 is higher than the Schottky barrier, which blocks the transition of electrons from the core of the first quantum dot QD1 to the outermost shell of the first quantum dot QD1, confines the electrons in the core of the first quantum dot QD1, and has a blocking effect on the injected electrons, so that may avoid the damage of the injection of electrons to the hole transport layer. In addition, 1.5 eV>ΔE_{CB,S1-C1}, the characteristics of the semiconductor material currently in use determine that the conduction band energy level barrier between the core and the shell may not exceed 1.5 eV, but the present disclosure does not limit the upper limit of the energy level barrier.

For the second quantum dot QD2, 0<ΔE_{CB,S2-core}; and ΔE_{VB,C2-S2}>0.4 eV. That is, for the second quantum dot QD2, the valence band energy level of the core of the second quantum dot QD2 is higher than that of the outermost shell, and the conduction band energy level of the core is lower than that of the outermost shell. The second quantum dot QD2 is a type I quantum dot, which has good confinement capability. ΔE_{VB,C2-S2}>0.4 eV, the valence band energy level barrier between the outermost shell and the core of the second quantum dot QD2 is higher than the Schottky barrier, which prevents holes from jumping from the outermost shell of the second quantum dot QD2 to the core of the second quantum dot QD2, and confines the holes in the shell of the second quantum dot QD2, which has a blocking effect on the holes injected, and may avoid the damage of the injection of holes to the electron transport layer. In addition, 1.5 eV>ΔE_{VB,C2-S2}, the characteristics of the semiconductor material currently in use determine that the conduction band energy level barrier between the core and the shell may not exceed 1.5 eV, but the present disclosure does not limit the upper limit of the energy level barrier.

The conventional quantum dot light-emitting layer only includes one kind of quantum dot material. In the one kind of quantum dot material, since the carriers need to be injected into the core from the shell, the barrier between the core and the shell, that is, the valence band energy level difference ΔE_{VB} and the conduction band energy level difference ΔE_{CB} may not be too high, resulting in that the barrier between the core and the shell does not play a good confinement role. In this QLED device structure, the LUMO energy level of the hole transport layer is generally used to confine the electrons, and the HOMO energy level of the electron transport layer is used to confine the holes, but the direct impact of the electrons and the holes may cause certain damage to the materials of the hole transport layer and the electron transport layer.

In the quantum dot composition of the present disclosure, the conduction band energy level of the outermost shell of the second quantum dot QD2 is lower than that of the outermost shell of the first quantum dot QD1, and the valence band energy level of the outermost shell of the second quantum dot QD2 is lower than that of the outermost shell of the first quantum dot QD1, so that the electrons and the holes are preferentially injected into the shell of the second quantum dot QD2, and then enter the core of the second quantum dot QD2 or the shell of the first quantum dot QD1 from the shell of the second quantum dot QD2. The first quantum dot QD1 with a shallow valence band energy level confines the electrons, and the second quantum dot QD2 with a deep conduction band energy level confines the holes, so that the energy level barriers are constructed to play a role in blocking and confining the holes and the electrons. That is, the electrons and the holes are respectively injected into the light-emitting layer through the shell energy level positions with smaller barriers, and are confined in the quantum dot light-emitting layer by the relatively large conduction band energy level and valence band energy level, so that the possibilities of the holes leaking to the electron transport layer and the electrons leaking to the hole transport layer are reduced, the attenuation of the carrier transport performance caused by the loss of the functional layer due to the high-density excitons is avoided, and meanwhile, the holes and the electrons confined in the quantum dot light-emitting layer have a higher probability of being combined to radiate light. In addition, by adjusting the ratio of the first quantum dot QD1 and the second quantum dot QD2, the carrier injection level may also be adjusted by using the constructed barrier. Therefore, the quantum dot light-emitting diode device has higher exciton combination efficiency, and may avoid the damage of the performance of the charge transport layer caused by the offset of the exciton recombination region.

In some embodiments, a material of the core of the first quantum dot QD1 is the same as a material of the core of the second quantum dot QD2. By selecting the same core of the quantum dot and coating different energy level structures of shells, the core-shell structure quantum dots with the same or similar band gap width are prepared, so that the consistency of the light-emitting wavelengths of the first quantum dot QD1 and the second quantum dot QD2 is improved, and the manufacturing steps and the manufacturing cost are simplified.

A difference between a full width at half maximum of the emission spectra of the first quantum dot QD1 and a full width at half maximum of the emission spectra of the second quantum dot QD2 ranges from 0 nm to 5 nm. If the difference between the full width at half maximum is greater than 5 nm, it indicates that the energy distribution difference of the two quantum dot materials is large, which is not conducive to obtaining the light-emitting consistent spectrum.

A thickness of at least one shell of the first quantum dot QD1 and a thickness of at least one shell of the second quantum dot QD2 are less than or equal to 10 nm. The energy level position and the thickness of the shell of the quantum dot determine the height and width of the potential barrier, and jointly affect the injection difficulty of the carriers. When the thickness of the shell of the quantum dot is less than or equal to 10 nm, the carriers may be transmitted in the tunneling mode and are not limited by the energy level position. Therefore, when the quantum dot material is synthesized, a thin layer (≤10 nm) of the wide band gap shell (CdZnS, ZnS, etc.) may be grown at the outermost layer to passivate the surface of the quantum dot, so that better optical stability is obtained.

Optionally, the material of the core and the material of the shell of the first quantum dot QD1 and the second quantum dot QD2 are independently selected from one or more of a group II-VI compound, a group IV-VI compound, a group III-V compound, and a group I-III-VI compound. The group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The group III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb. The group I-III-VI compound is selected from one or more of CuInS₂, CuInSe₂, and AgInS₂. The perovskite semiconductor material is selected from a doped or undoped inorganic perovskite semiconductor or an organic-inorganic hybrid perovskite semiconductor. The inorganic perovskite semiconductor has a general structure of AMX₃, the organic-inorganic hybrid perovskite semiconductor has a structure general formula of BMX₃, where A is a Cs⁺ ion; B is an organic amine cation selected from CH₃ (CH₂)ₙ₋₂NH₃⁺ or [NH₃ (CH₂)ₙNH₃]²⁺, n≥2; M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; and X is a halide anion selected from one or more of Cl⁻, Br⁻, and I⁻.

The quantum dot composition composed of two kinds of quantum dots is described above. However, the number of components in the quantum dot composition may be greater than 2. When the number of components in the quantum dot composition is greater than 3, the quantum dot composition includes at least the first quantum dot QD1 and the second quantum dot QD2. In addition to the first quantum dot QD1 and the second quantum dot QD2, the quantum dot composition may further include other quantum dots that meet the conditions of the first quantum dot QD1 or the second quantum dot QD2, or other quantum dots that do not meet the conditions of the first quantum dot QD1 or the second quantum dot QD2. When the other quantum dots meet the conditions of the first quantum dot QD1 or the second quantum dot QD2, the concentration of the first quantum dot QD1 or the second quantum dot QD2 is increased, thereby achieving the effect of adjusting the carrier balance. The conduction band energy level and the valence band energy level of the other quantum dots may be the same as or similar to those of the first quantum dot QD1 or the second quantum dot QD2. Alternatively, at least one of the conduction band energy level and the valence band energy level of the other quantum dots may also be greatly different from those of the first quantum dot QD1 or the second quantum dot QD2, thereby forming an energy level gradient, in this case, the energy level gradient formed by the other quantum dots between the first quantum dot QD1 or the second quantum dot QD2 is not conducive to carrier injection.

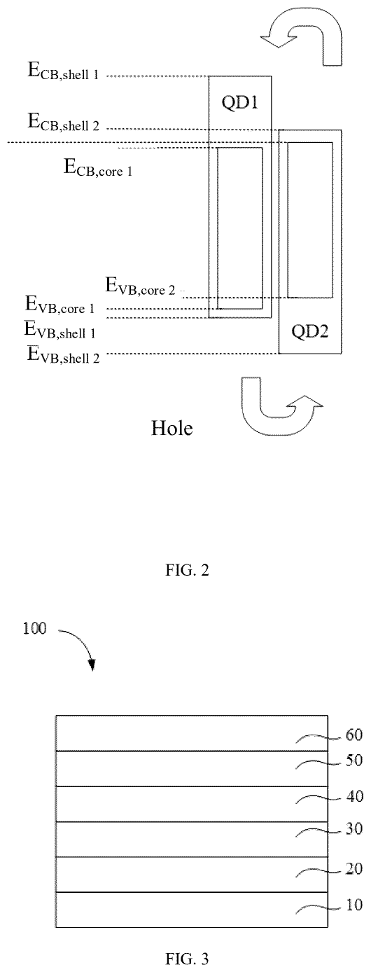

Referring to FIG. 2, another embodiment of the present disclosure further provides a quantum dot composition including a first quantum dot QD1 and a second quantum dot QD2. The first quantum dot QD1 and the second quantum dot QD2 are both core-shell quantum dots. A ratio of a band gap width of a core of the first quantum dot QD1 to a band gap width of a core of the second quantum dot QD2 is 1:(0.9-1.1). A conduction band energy level of an outermost shell of the second quantum dot QD2 is lower than a conduction band energy level of an outermost shell of the first quantum dot QD1, and a valence band energy level of the outermost shell of the second quantum dot QD2 is lower than a valence band energy level of an outermost shell of the first quantum dot QD1.

The first quantum dot QD1 satisfies 0<ΔE_{VB,C1-S1}≤0.4 eV and ΔE_{CB,S1-C1}>0.4 eV, and the second quantum dot QD2 satisfies 0<ΔE_{CB,S2-C2} and ΔE_{VB,C2-S2}>0.4 eV, where ΔE_{VB,C1-S1}=E_{VB,C1}−E_{VB,S1}, ΔE_{CB,S1-C1}=E_{CB,S1}−E_{CB,C1}, ΔE_{VB,C2-S2}=E_{VB,C2}−E_{VB,S2}, and ΔE_{CB,S2-C2}=E_{CB,S2}−E_{CB,C2}.

In this embodiment, as long as the band gap width of the core of the first quantum dot QD1 is close to the band gap width of the core of the second quantum dot QD2, the first quantum dot QD1 and the second quantum dot QD2 may emit light of similar wavelengths. Optionally, the band gap width of the core of the first quantum dot QD1 is the same as the band gap width of the core of the second quantum dot QD2. Being same as the embodiment of FIG. 1, the quantum dot composition includes the first quantum dot QD1 with a shallow valence band and the second quantum dot QD2 with a deep conduction band energy level, and the carrier balance injected into the quantum dot light-emitting layer may be controlled by adjusting the ratio of the first quantum dot QD1 and the second quantum dot QD2. The first quantum dot QD1 and the second quantum dot QD2 are both type I quantum dots and have confinement capability. The valence band energy level barrier between the shell and the core of the first quantum dot QD1 is lower than the Schottky barrier, which is conducive to the injection of holes from the shell to the core of the first quantum dot QD1. The conduction band energy level barrier between the shell and the core of the first quantum dot QD1 is higher than the Schottky barrier, which blocks the injection of electrons. The valence band energy level barrier between the shell and the core of the second quantum dot QD2 is higher than the Schottky barrier, which blocks the injection of holes.

Optionally, a ratio of the band gap width of the core of the first quantum dot QD1 to the band gap width of the core of the second quantum dot QD2 is 1:(0.95-1.05). Optionally, a ratio of a conduction band energy level of the core of the first quantum dot Q1 to a conduction band energy level of the core of the second quantum dot Q2 is 1:(0.9-1.1), and a ratio of a valence band energy level of the core of the first quantum dot Q1 to a valence band energy level of the core of the second quantum dot Q2 is 1:(0.9-1.1), but is not limited thereto. Optionally, the ratio of the conduction band energy level of the core of the first quantum dot Q1 to the conduction band energy level of the core of the second quantum dot Q2 is 1:(0.95-1.05), and the ratio of the valence band energy level of the core of the first quantum dot Q1 to the valence band energy level of the core of the second quantum dot Q2 is 1:(0.95-1.05).

Optionally, the first quantum dot QD1 satisfies: 1.5 eV>ΔE_{CB,S1-C1}, and the conduction band energy level barrier between the core and the shell is less than 1.5 eV.

Optionally, the second quantum dot QD2 satisfies ΔE_{CB,S2-C2}≤0.4 eV.

Optionally, the second quantum dot QD2 satisfies: 1.5 eV>ΔE_{VB,C2-S2}, and the valence band energy level barrier between the core and the shell is less than 1.5 eV.

The solubilities of quantum dots with different shell structures in organic solvents are not significantly different, thereby the problem of aggregation and sedimentation of mixed multi-components quantum dots may be avoided. A solvent for dispersing the quantum dot includes one or more of chloroform, toluene, n-hexane, cyclohexane, n-heptane, n-octane, cycloheptane, and dioxane.

In one embodiment, the core of the quantum dot is CdSe, and a CdS shell and a ZnSe shell are coated respectively on the core, and the quantum dot light-emitting wavelengths are controlled to be consistent. The conduction band energy level difference ΔE_{CB, shell-core} of CdSe/CdS is about 0.3 eV, the valence band energy level difference ΔE_{CB, core-shell} is about 0.5 eV. The conduction band energy level difference ΔE_{CB,shell-core} of CdSe/ZnSe is about 1 eV, and the valence band energy level difference ΔE_{CB,core-shell} is about 0.1 eV. The CdSe/CdS and the CdSe/ZnSe meet the requirements of the quantum dot composition, and the emission wavelengths are both 635 nm, and the full widths at half maximum are 25 nm and 24 nm respectively. In a red quantum dot light-emitting device, there is a carrier imbalance problem, so a mass ratio of CdSe/ZnSe to CdSe/CdS is set to 1:1. The band gap of the red quantum dot material is narrow, the energy level position is conducive to the injection of electrons and holes, thereby the exciton density in the light-emitting layer is high, the shallow conduction band energy level of CdSe/ZnSe and the deep valence band energy level of CdSe/CdS are conducive to confining the electrons and holes in the light-emitting layer, thus the transmission performance attenuation of the charge transport layer caused by leakage is avoided. Compared with the device in which the CdSe/ZnSe and CdSe/CdS are used as the light-emitting layer respectively, the external quantum efficiency and the lifetime of the device are improved due to the conduction band energy level and valence band energy level which limit the injection levels of the electrons and the holes respectively.

In another embodiment, the core of the quantum dot is CdZnSeS, and a CdZnS/ZnS shell (the thickness of the ZnS shell is 1 nm, which is tunable and does not affect the injection barrier) and a ZnSe/ZnS shell (the thickness of the ZnS shell is 1 nm, which is tunable and does not affect the injection barrier) are coated respectively on the core, and controls the emission wavelength of the quantum dots to be consistent. The conduction band energy level difference of CdZnSeS/CdZnS/ZnS ΔE_{CB, shell-core} is about 0.2 eV, and the valence band energy level difference ΔE_{CB, core-shell} is about 0.7 eV. The conduction band energy level difference of CdZnSeS/ZnSe/ZnS ΔE_{CB,shell-core} is about 0.8 eV, and the valence band energy level difference ΔE_{CB, core-shell} is about 0.15 eV. The CdZnSeS/CdZnS/ZnS and the CdZnSeS/ZnSe/ZnS meet the requirements of the mixed quantum dot light-emitting layer, and the emission wavelengths are both 538 nm, and the full widths at half maximum are 26 nm and 25 nm respectively. In a green quantum dot light-emitting diode device, there is a carrier imbalance problem, so a mass ratio of CdZnSeS/CdZnS/ZnS to CdZnSeS/ZnSe/ZnS is set to 3:1 to achieve the effect of reducing the hole injection barrier and blocking part of the electrons, so that the carriers in the light-emitting layer are balanced. In addition, the shallow conduction band energy level of CdZnSeS/CdZnS/ZnS and the deep valence band energy level of CdZnSeS/ZnSe/ZnS are conducive to confining the electrons and the holes in the light-emitting layer, and avoid the leakage to cause the transmission performance of the charge transport layer to decay. Compared with the device in which the CdZnSeS/CdZnS/ZnS and the CdZnSeS/ZnSe/ZnS are used as the light-emitting layer alone, the conduction band energy level and the valence band energy level respectively limit the injection levels of the electrons and the holes, so that the external quantum efficiency and the lifetime of the device are improved.

Referring to FIG. 3 and FIG. 4, the present disclosure further provides a quantum dot light-emitting device 100 including an anode 10, a hole injection layer 20, a hole transport layer 30, a quantum dot light-emitting layer 40, an electron transport layer 50, and a cathode 60 which are sequentially stacked. The quantum dot light-emitting layer 40 includes the quantum dot composition.

The quantum dot light-emitting device 100 of the present disclosure includes the quantum dot composition, the first quantum dot QD1 with a shallow valence band energy level confines the electrons, and the second quantum dot QD2 with a deep conduction band energy level confines the holes, so that the energy level barriers are constructed to play a role in blocking and confining the holes and the electrons. In addition, by adjusting the ratio of the first quantum dot QD1 to the second quantum dot QD2, the constructed barriers may also be used to adjust the carrier injection level.

Optionally, the valence band energy level difference between the outermost shell of the first quantum dot QD1 and the hole transport layer 30 satisfies ΔE_{HTL-S1}=E_{LUMO,HTL}−E_{VB,S1}<0.5 eV, and the conduction band energy level difference between the outermost shell of the second quantum dot QD2 and the electron transport layer 50 satisfies ΔE_{EML-ETL}=E_{CB,S2}−E_{HOMO,ETL}<0.4 eV. A valence band energy level difference between the outermost shell of the quantum dot and a material of the hole transport layer 30 is greater than or equal to 0.5 eV, thereby the hole injection efficiency is reduced by increasing the hole injection barrier. The conduction band bottom energy level difference between the outermost shell of the quantum dot and a material of the electron transport layer 50 is less than 0.4 eV, thereby the electron injection efficiency is increased by reducing the electron injection barrier. Thereby the hole and electron injection balance in the light-emitting layer 40 is balanced. For example, in the quantum dot light-emitting device, the conduction band energy level of a red quantum dot, the conduction band energy level of a green quantum dot, and the conduction band energy level of a blue quantum dot respectively range from −4 eV to −3.5 eV, and the valence band energy level of a red quantum dot, the conduction band energy level of a green quantum dot, and the conduction band energy level of a blue quantum dot respectively range from −6.5 eV to −6 eV. Common material of the hole transport layer 30 includes PVK, Poly-TPD, CBP, TCTA and TFB, and the HOMO energy level of the material of the hole transport layer 30 ranges from −6 eV to −5.2 eV. Common material of the electron transport layer 50 includes n-type ZnO and doping Al, Mg, Ga, Sn and the like, and the LUMO energy level ranges from −4.3 eV to −3.4 eV. For different red quantum dot, green quantum dot and blue quantum dot, the band gap of blue quantum dot is the largest, and the energy level barrier between the blue quantum dot and the adjacent functional layer is larger than that of red quantum dot and green quantum dot, that is, the maximum electron barrier ΔE_{VB,max} between the blue quantum dot light-emitting layer and the electron transport layer 50 is about 0.8 eV, and the maximum hole barrier ΔE_{VB,max} between the blue quantum dot light-emitting layer and the hole transport layer 30 is about 1.3 eV. The conduction band energy level barrier between the quantum dot light-emitting layer and the electron transport layer 50 and the valence band energy level barrier between the quantum dot light-emitting layer and the hole transport layer 30 are too large, so that the electrons and the holes need to overcome a large energy level barrier and may not be effectively injected into the quantum dot light-emitting layer. Therefore, by adjusting the energy level position of the quantum dot light-emitting layer, the conduction band energy level and the valence band energy level are better matched with the energy levels of the corresponding transport functional layer, which is conducive to the efficient injection of carriers, and meanwhile, the appropriate adjustment of the energy level matching may effectively adjust the carrier balance injected into the light-emitting layer 40.

According to the performance characteristics of the material of the existing light-emitting layer and the carrier transport layer, to ensure that the carriers may be effectively injected and transported to the light-emitting layer for radiation recombination light emitting, the quantum dot in the light-emitting layer is required to satisfy: the conduction band energy level difference between the quantum dot component with the deepest conduction band bottom in the light-emitting layer 40 and the electron transport layer 50 satisfies ΔE_{EML-ETL}=E_{CB,S2}−E_{HOMO,ETL}<0.4 eV, and the valence band energy level difference between the quantum dot component with the shallowest valence band top in the light-emitting layer 40 and the hole transport layer 30 satisfies ΔE_{HTL-EML}=ΔE_{HTL-S1}=E_{LUMO,HTL}−E_{VB,S1}<0.5 eV.

Optionally, the anode 10 and the cathode 60 are independently selected from a doped metal oxide particle electrode, a composite electrode, a graphene electrode, a carbon nanotube electrode, a metal electrode, or an alloy electrode. The doped metal oxide particle electrode is selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide. The composite electrode is selected from AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, or ZnS/Al/ZnS. The metal electrode is selected from one or more of Ag, Al, Cu, Au, Mo, Pt, Ca, and Ba.

Optionally, the material of the electron transport layer 50 is selected from one or more of a metal oxide, a doped metal oxide, a 2-6 group semiconductor material, a 3-5 group semiconductor material, and a 1-3-6 group semiconductor material, the metal oxide is selected from one or more of ZnO, BaO, TiO₂, and SnO₂. A metal oxide of the doped metal oxide is selected from one or more of ZnO, TiO₂, and SnO₂, and a doping element of the doped metal oxide is selected from one or more of Al, Mg, Li, In, and Ga. The 2-6 group semiconductor material is selected from one or more of ZnS, ZnSe, and CdS. The 3-5 group semiconductor material is selected from one or more of InP and GaP. The 1-3-6 group semiconductor material is selected from one or more of CuInS and CuGaS.

Optionally, the material of the hole transport layer 30 is selected from one or more of 4,4′-N,N′-dicarbazolyl-biphenyl (CBP), N,N′-diphenyl-N,N′-bis(1-naphthyl)-1,l′-biphenyl-4,4″-diamine, N,N′-diphenyl-N,N′-bis(3-methylphenyl)-(1,1′-biphenyl)-4,4′-diamine, N,N′-bis(3-methylphenyl)-N,N′-bis(phenyl)-spiro(spiro-TPD), N,N′-di(4-(N,N′-diphenyl-amino)phenyl)-N,N′-diphenylbenzidine, 4,4′,4′-tris(N-carbazolyl)-triphenylamine, 4,4′,4′-tris(N-3-methylphenyl-N-phenylamino)triphenylamine, poly[(9,9′-dioctylfluorene-2,7-diyl)-co-(4,4′-(N-(4-sec-butyphenyl)diphenylamine))], poly(4-butylphenyl-diphenylamine) (poly-TPD), polyaniline, polypyrrole, poly(p) phenylenevinylene, poly(phenylenevinylene), poly[2-methoxy-5-(2-ethylhexyloxy)-1,4-phenylenevinylene], poly[2-methoxy-5-(3′,7′-dimethyloctyloxy)-1,4-phenylenevinylene], copper phthalocyanine, aromatic tertiary amines, polynuclear aromatic tertiary amines, 4,4′-bis(carbazol-9-yl)-1,1′-biphenyl compounds, N,N,N′,N′-tetraarylbenzidines, PEDOT:PSS and derivatives thereof, poly(N-vinylcarbazole) (PVK) and derivatives thereof, polymethacrylates and derivatives thereof, poly(9,9-octylfluorene) and derivatives thereof, poly(spirofluorene) and derivatives thereof, N,N′-di(naphthalen-1-yl)-N,N′-diphenylbenzidine, spiro-NPB, doped graphene, non-doped graphene, C60, doped or non-doped NiO, doped or non-doped MoO₃, doped or non-doped WO₃, doped or non-doped V₂O₅, doped or non-doped P-type gallium nitride, doped or non-doped CrO₃, and doped or non-doped CuO.

Optionally, the material of the hole injection layer 20 is selected from one or more of 2,3,6,7,10,11-hexacyano-1,4,5,8,9,12-hexaazatriphenylene, PEDOT, PEDOT:PSS, derivatives of PEDOT:PSS doped with s-MoO₃, 4,4′,4′-tris(N-3-methylphenyl-N-phenylamino)triphenylamine, tetracyanoquinodimethane, copper phthalocyanine, nickel oxide, molybdenum oxide, tungsten oxide, vanadium oxide, molybdenum sulfide, tungsten sulfide, and copper oxide.

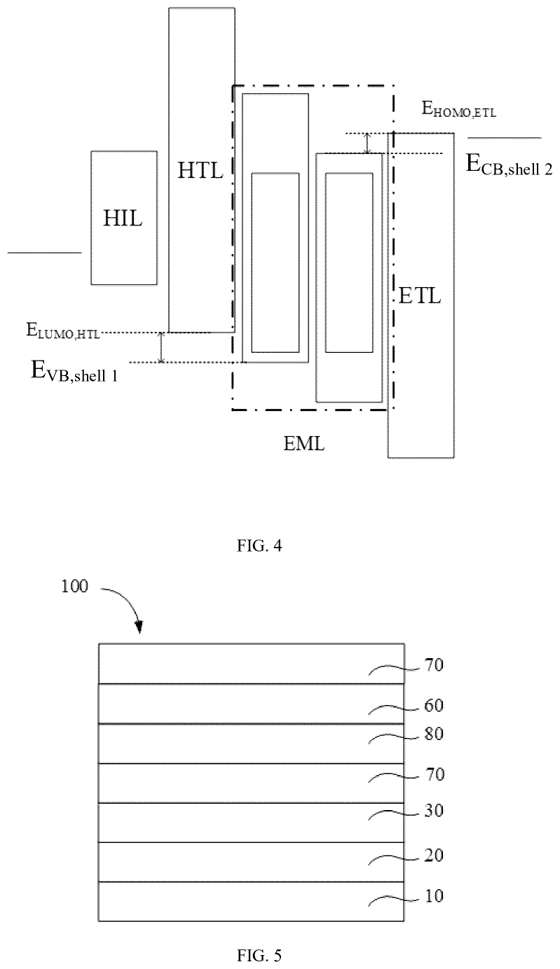

Referring to FIG. 5, the present disclosure further provides another quantum dot light-emitting device 100, which includes an anode 10, a hole injection layer 20, a hole transport layer 30, a first quantum dot light-emitting layer 70, a second quantum dot light-emitting layer 80, an electron transport layer 50 and a cathode 60 which are sequentially stacked. The first quantum dot light-emitting layer 70 includes the first quantum dot QD1, and the second quantum dot light-emitting layer 80 includes the second quantum dot QD2. The first quantum dot QD1 and the second quantum dot QD2 are both core-shell quantum dots. A ratio of a conduction band energy level of a core of the first quantum dot QD1 to a conduction band energy level of a core of the second quantum dot QD2 is 1:(0.9-1.1), and a ratio of a valence band energy level of the core of the first quantum dot QD1 to a valence band energy level of the core of the second quantum dot QD2 is 1:(0.9-1.1). A conduction band energy level of an outermost shell of the second quantum dot QD2 is lower than a conduction band energy level of an outermost shell of the first quantum dot QD1, and a valence band energy level of the outermost shell of the second quantum dot QD2 is lower than a valence band energy level of the outermost shell of the first quantum dots QD1. The first quantum dot QD1 satisfies 0<ΔE_{VB,C1-S1}≤0.4 eV and ΔE_{CB,S1-C1}>0.4 eV, and the second quantum dot QD2 satisfies 0<ΔE_{CB,S2-C2}≤0.4 eV and ΔE_{VB,C2-S2}>0.4 eV, where ΔE_{VB,C1-S1}=E_{VB,C1}−E_{VB,S1}, ΔE_{CB,S1-C1}=E_{CB,S1}−E_{CB,C1}, ΔE_{VB,C2-S2}=E_{VB,C2}−E_{VB,S2}, and ΔE_{CB,S2-C2}=E_{CB,S2}−E_{CB,C2}, and C1, S1, C2 and S2 respectively represent the core and the shell of the first quantum dots and the core and the shell of the second quantum dots.

The quantum dot light-emitting device 100 of this embodiment is different from the quantum dot light-emitting device 100 of FIG. 3 in that: the quantum dot light-emitting device 100 of FIG. 3 is to mix the first quantum dots QD1 and the second quantum dot QD2, and the carriers preferentially enter the quantum dot with low energy level; however, in this embodiment, the carriers preferentially enter the quantum dot light-emitting layer 40 closer to the carrier transport layer. That is, the electrons preferentially enter the second quantum dot light-emitting layer 80 from the electron transport layer 50, and the holes preferentially enter the first quantum dot light-emitting layer 70 from the hole transport layer 30. Since the multilayer quantum dot light-emitting layer 40 is used, the quantum dot light-emitting device 100 of the embodiment may also achieve similar effects to the quantum dot light-emitting device 100 of FIG. 3. For example, the carrier balance is controlled by regulating the content of the quantum dot in the light-emitting layer, and the carriers are bound.

Since the multilayer quantum dot light-emitting layers may dissolve each other to damage the light-emitting film in the manufacturing process t, a cross-linking method may be used to form a stable quantum dot light-emitting layer first, and then another quantum dot light-emitting layer is formed.

Optionally, the valence band energy level difference between the outermost shell of the first quantum dot QD1 and the hole transport layer 30 satisfies ΔE_{HTL-S1}=E_{LUMO,HTL}−E_{VB,S1}<0.5 eV, and the conduction band energy level difference between the outermost shell of the second quantum dot QD2 and the electron transport layer 50 satisfies ΔE_{EML-ETL}=E_{CB,S2}−E_{HOMO,ETL}<0.4 eV. The valence band top energy level difference between the outermost shell of the quantum dot and the material of the hole transport layer is greater than or equal to 0.5 eV, the hole injection efficiency is reduced by increasing the hole injection barrier; the conduction band bottom level difference between the outermost shell of the quantum dot and the material of the electron transport layer is less than 0.4 eV, the electron injection efficiency is increased by reducing the electron injection barrier. Thereby the hole and electron injection balance in the light-emitting layer is balanced.

Hereinafter, the present disclosure will be specifically described with reference to specific examples, and the following examples are only partial examples of the present disclosure and do not limit the present disclosure.

### Example 1

Synthesis of red quantum dots CdSe/ZnSe and CdSe/CdS: PL=635 nm, FWHM=25 nm and 24 nm.

(1) Preparation of precursor solution: 10 mmol of selenium powder and 10 mL of TOP were weighed and mixed to prepare a 1M Se/TOP anion precursor solution; 10 mmol of sulfur and 10 mL of TOP were weighed and mixed to prepare a 1M S/TOP anion precursor solution; 5 mmol of cadmium oxide, 5 ml of oleic acid and 20 mL of octadecene were weighed and placed in a three-necked flask, then heated to 100° C., vacuumized, and treated with water and oxygen until the treatment was completed, argon was introduced, the temperature was raised to 260° C., thereby a clear and transparent 0.2M Cd(OA)₂ was formed, and then the temperature was lowered to room temperature; 10 mmol of zinc acetate, 10 mL of oleic acid and 10 mL of octadecene were weighed and placed in a three-necked flask, then heated to 100° C., vacuumized, argon was introduced after water and oxygen treatment was completed, the temperature was raised to 260° C., thereby a clear and transparent 0.5M Zn(OA)₂ was formed, and then the temperature was lowered to 100° C. for insulation.

(2) 0.4 mmol of cadmium oxide, 5 mL of oleic acid and 15 mL of octadecene were weighed and placed in a three-necked flask, then heated to 100° C., vacuumized, argon was introduced after water and oxygen treatment was completed, and the temperature was raised to 260° C.; when the temperature was stable, 0.4 mL of 1M selenium anion precursor solution was injected into the reaction system, and aged 1 h to obtain a CdSe core of the quantum dot.

(3) The temperature of the reaction system was lowered to 240° C., 1 mL of 1M selenium anion and 4 mL of Zn(OA)₂ were added dropwise into the reaction system, and the addition was completed in 30 min, thereby the ZnSe shell was grown, and the CdSe/ZnSe core-shell quantum dot was obtained. Similarly, 1 mL of 1M sulfur anion and 2 mL of Cd(OA)₂ were added dropwise into the core of the quantum dot reaction system, the addition was completed in 30 min, and the CdS shell was grown to obtain the CdSe/CdS core-shell quantum dot.

(5) After the reaction was completed, the temperature was lowered to room temperature, and the obtained quantum dots were washed, purified, and prepared into a 15 mg/mL n-octane solution.

(6) Mixed quantum dot solution: 1 mL of CdSe/CdS solution and 1 mL of CdSe/ZnSe solution were taken respectively and mixed.

### Preparation of QLED:

PEDOT:PSS material was spin-coated on an ITO anode 10 with a material of ITO to form a hole injection layer having a thickness of 50 nm, and then annealed at 100° C. for 15 min; a TFB hole transport layer having a thickness of 30 nm was formed thereon, and then annealed at 100° C. for 15 min; a mixed quantum dot light-emitting layer having a thickness of 15 nm was formed on the hole transport layer, and then annealed at 100° C. for 10 min to remove the solvent; an ethanol solution of ZnO was prepared on the light-emitting layer, and heat annealed on a hot plate at 80° C. for 10 min to obtain an electron transport layer having a thickness of 30 nm; finally, an Ag cathode electrode layer was formed by evaporation, and then encapsulated to form the light-emitting device.

The photoelectric performance and the lifetime of the quantum dot light-emitting device were tested, and the test results are shown in Table 1.

The lifetime test of the device adopted a 128-channel lifetime test system customized by Guangzhou New Horizon Company. The system architecture is that a constant voltage or a constant current source drive the QLED to test the change of voltage or current; a photodiode detector and a test system were used to test the change of brightness (photoelectric current) of the QLED; and a luminance meter was used to test and calibrate the brightness (photoelectric current) of the QLED.

### Example 2

Synthesis of green quantum dots CdZnSeS/CdZnS/ZnS and CdZnSeS/ZnSe/ZnS: PL=538 nm, FWHM=26 nm and 25 nm.

(1) Preparation of precursor solution: Se/TOP, S/TOP, Cd(OA)₂ and Zn(OA)₂ were prepared in the same method as in Example 1.

(2) 0.2 mmol of cadmium oxide, 5 mmol of zinc acetate, 5 mL of oleic acid and 15 mL of octadecene were weighed and placed in a three-neck flask, then heated to 100° C., vacuumized, argon was introduced after water and oxygen treatment was completed, and the temperature was raised to 320° C.; after the temperature was stabilized, 1 mL of 1M selenium and 1 mL of 1M sulfur anion mixed precursor solution were injected into the reaction system, and aged for 30 min to obtain a CdZnSeS core of the quantum dot.

(3) The temperature of the reaction system was reduced to 280° C., 3 mL of 1M selenium anion and 5 mL of 0.2M Cd(OA)₂ were added dropwise into the reaction system, and the addition was completed in 100 min, thereby the CdZnS shell was completed, and a CdZnSeS/CdZnS core-shell quantum dot. Then, 0.5 mL of 1M sulfur anion precursor was added dropwise to grow a thin ZnS shell of about 1 nm to obtain the CdZnSeS/CdZnS/ZnS core-shell quantum dot. Similarly, 2 mL of 1M selenium anion was added into the reaction system of the core of the quantum dot, and the growth was completed in 30 min; then, 0.5 mL of 1M sulfur anion precursor was added dropwise to grow a thin ZnS shell of about 1 nm to obtain the CdZnSeS/ZnSe/ZnS core-shell quantum dot.

(5) After the reaction was completed, the temperature was reduced to room temperature, and the obtained quantum dots were washed, purified, and prepared into a 20 mg/mL n-octane solution.

(6) Mixed quantum dot solution: 1 mL of CdZnSeS/CdZnS/ZnS solution and 1 mL of CdZnSeS/ZnSe/ZnS solution were taken respectively and mixed.

### Preparation of QLED:

PEDOT:PSS material was spin-coated on an anode 10 with a material of ITO to form a hole injection layer having a thickness of 50 nm, and then annealed at 100° C. for 15 min; a TFB hole transport layer having a thickness of 30 nm was formed thereon, and then annealed at 100° C. for 15 min; a mixed quantum dot light-emitting layer having a thickness of 15 nm was formed on the hole transport layer, and then annealed at 100° C. for 10 min to remove the solvent; an ethanol solution of ZnO was prepared on the light-emitting layer, and heat annealed on a hot plate at 80° C. for 10 min to obtain an electron transport layer having a thickness of 30 nm; finally, an Ag cathode electrode layer was formed by evaporation, and then encapsulated to form the light-emitting device.

The photoelectric performance and the lifetime of the quantum dot light-emitting device were tested, and the test results are shown in Table 1.

### Comparative Example 1

The synthesis process of the quantum dot in Comparative Example 1 was basically the same as that of Example 1, except that the quantum dot was CdSe/ZnSe.

The photoelectric performance and the lifetime of the quantum dot light-emitting device were tested, and the test results are shown in Table 1.

### Comparative Example 2

The synthesis process of the quantum dot in Comparative Example 2 was basically the same as that of Example 1, except that the quantum dot was CdSe/ZnSe.

The photoelectric performance and the lifetime of the quantum dot light-emitting device were tested, and the test results are shown in Table 1.

### Comparative Example 3

The synthesis process of the quantum dot in Comparative Example 3 was basically the same as that of Example 2, except that the quantum dot was CdZnSeS/CdZnS/ZnS.

The photoelectric performance and the lifetime of the quantum dot light-emitting device were tested, and the test results are shown in Table 1.

### Comparative Example 4

The synthesis process of the quantum dot in Comparative Example 4 was basically the same as that of Example 2, except that the quantum dot was CdZnSeS/ZnSe/ZnS.

The photoelectric performance and the lifetime of the quantum dot light-emitting diode device were tested, and the test results are shown in Table 1.

TABLE 1
Device performance comparison of Example 1, Example
2, Comparative Example 1, Comparative Example 2,
Comparative Example 3, Comparative Example 4.

| | | | LT₉₅@1000 |
|---|---|---|---|
| | Light-emitting layer | EQE(%) | nit (h) |
| Example 1 | CdSe/ZnSe:CdSe/ | 18 | 2600 |
| | CdS = 1:1 | | |
| Example 2 | CdZnSeS/CdZnS/ | 21 | 5500 |
| | ZnS:CdZnSeS/ | | |
| | ZnSe/ZnS = 3:1 | | |
| Comparative | CdSe/ZnSe | 8 | 800 |
| Example 1 | | | |
| Comparative | CdSe/CdS | 11 | 1200 |
| Example 2 | | | |
| Comparative | CdZnSeS/CdZnS/ZnS | 12 | 2300 |
| Example 3 | | | |
| Comparative | CdZnSeS/ZnSe/ZnS | 9 | 1900 |
| Example 4 | | | |

Compared with the devices in Comparative Example 1 and Comparative Example 2 in which separate components of CdSe/ZnSe and CdSe/CdS were used as the light-emitting layer, and the external quantum efficiency (EQE) is 8% and 11% respectively due to the conduction band and valence band energy levels limit the injection level of electrons and holes respectively. In Example 1, the quantum dot light-emitting device was prepared by using the mixed quantum dot CdSe/ZnSe and CdSe/CdS as the light-emitting layer, thereby the external quantum efficiency of 18% was obtained. The lifetime (T95@1000 nit) of the devices was tested in a constant current mode of 2 mA/cm², the quantum dots of the mixed light-emitting layer limit the carriers, thereby reducing the damage to the charge transport layer, and the lifetime of the device of the example 1 is 2600 h. In the device of Comparative Example 1, quantum dots of the light-emitting layer have poor limitation on electrons or holes, resulting in obvious performance decay of the device, and the lifetime of the devices based on CdSe/ZnSe and CdSe/CdS as the light-emitting layer is 800 h and 1200 h respectively. The results further show that the mixed quantum dot light-emitting layer of the present disclosure may effectively improve the performance of the QLED device.

Compared with the devices in Comparative Example 3 and Comparative Example 4 in which separate components of CdZnSeS/CdZnS/ZnS and CdZnSeS/ZnSe/ZnS were used as the light-emitting layer alone, and the external quantum efficiency (EQE) is 12% and 9% respectively due to the conduction band and valence band energy levels limiting the injection level of electrons and holes respectively. In Example 2, the quantum dot light-emitting device was prepared by using the mixed quantum dot CdZnSeS/CdZnS/ZnS and CdZnSeS/ZnSe/ZnS as the light-emitting layer, thereby the external quantum efficiency of 21% was obtained. The lifetime (T95@1000 nit) of the device were tested in the constant current mode 2 mA/cm², the confinement effect of the quantum dots of the mixed light-emitting layer limit the carriers, thereby reducing the damage to the charge transport layer, and the lifetime of the device of the example 2 is 5500 h. In the device of Comparative Example 2, quantum dots in the light-emitting layer have poor limitation on electrons or holes, resulting in obvious performance decay of the device, and the working lifetime of the devices based on CdZnSeS/CdZnS/ZnS and CdZnSeS/ZnSe/ZnS as the light-emitting layer is 2300 h and 1900 h respectively. The results further show that the mixed quantum dot light-emitting layer of the present disclosure scheme may effectively improve the performance of the QLED device.

The technical solutions provided by the embodiments of the present disclosure are described in detail above. The principles and embodiments of the present disclosure have been described with reference to specific embodiments, and the description of the above embodiments is merely intended to aid in the understanding of the method of the present disclosure and its core idea. Meanwhile, for those skilled in the art, the specific implementation manners and application ranges may be changed according to the idea of the present disclosure. In conclusion, the content of the specification should not be understood as a limitation on the present disclosure.

1. A quantum dot composition, comprising:
a first quantum dot and a second quantum dot, the first quantum dot and the second quantum dot are both core-shell quantum dots, a ratio of a conduction band energy level of a core of the first quantum dot to a conduction band energy level of a core of the second quantum dot is 1:(0.9-1.1), a ratio of a valence band energy level of the core of the first quantum dot to a valence band energy level of the core of the second quantum dot is 1:(0.9-1.1), a conduction band energy level of an outermost shell of the second quantum dot is lower than a conduction band energy level of an outermost shell of the first quantum dot, and a valence band energy level of the outermost shell of the second quantum dot is lower than a valence band energy level of the outermost shell of the first quantum dot;
wherein the first quantum dot satisfies 0<ΔE_{VB,C1-S1}≤0.4 eV and ΔE_{CB,S1-C1}>0.4 eV, and the second quantum dot satisfies 0<ΔE_{CB,S2-C2}≤0.4 eV and ΔE_{VB,C2-S2}>0.4 eV;
ΔE_{VB,C1-S1}=E_{VB,C1}−E_{VB,S1}, ΔE_{CB,S1-C1}=E_{CB,S1}−E_{CB,C1}, ΔE_{VB,C2-S2}=E_{VB,C2}−E_{VB,S2}, ΔE_{CB,S2-C2}=E_{CB,S2}−E_{CB,C2}, where C1, S1, C2, and S2 respectively represent the core and the shell of the first quantum dot and the core and the shell of the second quantum dot.

2. The quantum dot composition of claim 1, wherein a material of the core of the first quantum dot is the same as material of the core of the second quantum dot.

3. The quantum dot composition of claim 1, wherein a difference between the full width half maximum of the emission spectra of the first quantum dot and a full width at half maximum of the emission spectra of the second quantum dot ranges from 0 nm to 5 nm.

4. The quantum dot composition of claim 1, wherein a thickness of at least one shell of the first quantum dot and a thickness of at least one shell of the second quantum dot are less than or equal to 10 nm.

5. The quantum dot composition of claim 1, wherein the conduction band energy level of the core of the first quantum dot is not more than 10% different from the conduction band energy level of the core of the second quantum dot, and the valence band energy level of the core of the first quantum dot is not more than 10% different from the valence band energy level of the core of the second quantum dot.

6. The quantum dot composition of claim 1, wherein the ratio of the conduction band energy level of the core of the first quantum dot to the conduction band energy level of the core of the second quantum dot is 1:(0.95-1.05), and the ratio of the valence band energy level of the core of the first quantum dot to the valence band energy level of the core of the second quantum dot is 1:(0.95-1.05).

7. The quantum dot composition of claim 1, wherein the conduction band energy level of the core of the first quantum dot is the same as the conduction band energy level of the core of the second quantum dot, and the valence band energy level of the core of the first quantum dot is the same as the valence band energy level of the core of the second quantum dot.

8. The quantum dot composition of claim 1, wherein a material of the core and a material of the shell of the first quantum dot and the second quantum dot are independently selected from one or more of a group II-VI compound, a group IV-VI compound, a group III-V compound, and a group I-III-VI compound, the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the group I-III-VI compound is selected from one or more of CuInS₂, CuInSe₂, and AgInS₂; the perovskite semiconductor material is selected from a doped or undoped inorganic perovskite semiconductor or an organic-inorganic hybrid perovskite semiconductor, the inorganic perovskite semiconductor has a general structure of AMX₃, the organic-inorganic hybrid perovskite semiconductor has a structure general formula of BMX₃, where A is a Cs⁺ ion; B is an organic amine cation selected from CH₃(CH₂)ₙ₋₂NH₃⁺ or [NH₃(CH₂)ₙNH₃]²⁺, n≥2; M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; and X is a halide anion selected from one or more of Cl⁻, Br⁻, and I⁻.

9. A quantum dot composition, comprising:
a first quantum dot and a second quantum dot, the first quantum dot and the second quantum dot are both core-shell quantum dots, a ratio of a band gap width of a core of the first quantum dot to a band gap width of a core of the second quantum dot is 1:(0.9-1.1), a conduction band energy level of an outermost shell of the second quantum dot is lower than a conduction band energy level of an outermost shell of the first quantum dot, and a valence band energy level of the outermost shell of the second quantum dot is lower than a valence band energy level of the outermost shell of the first quantum dot;
wherein the first quantum dot satisfies 0<ΔE_{VB,C1-S1}≤0.4 eV and ΔE_{CB,S1-C1}>0.4 eV, and the second quantum dot satisfies 0<ΔE_{CB,S2-C2} and ΔE_{VB,C2-S2}>0.4 eV;
ΔE_{VB,C1-S1}=E_{VB,C1}−E_{VB,S1}, ΔE_{CB,S1-C1}=E_{CB,S1}−E_{CB,C1}, ΔE_{VB,C2-S2}=E_{VB,C2}−E_{VB,S2}, and ΔE_{CB,S2-C2}=E_{CB,S2}−E_{CB,C2}, where C1, S1, C2 and S2 respectively represent the core and the shell of the first quantum dot and the core and the shell of the second quantum dot.

10. The quantum dot composition of claim 9, wherein the ratio of the band gap width of the core of the first quantum dot to the band gap width of the core of the second quantum dot is 1:(0.95-1.05).

11. The quantum dot composition of claim 9, wherein a ratio of a conduction band energy level of the core of the first quantum dot to a conduction band energy level of the core of the second quantum dot is 1:(0.9-1.1), and a ratio of a valence band energy level of the core of the first quantum dot to a valence band energy level of the core of the second quantum dot is 1:(0.9-1.1).

12. The quantum dot composition of claim 9, wherein a ratio of a conduction band energy level of the core of the first quantum dot to a conduction band energy level of the core of the second quantum dot is 1:(0.95-1.05), and a ratio of a valence band energy level of the core of the first quantum dot to a valence band energy level of the core of the second quantum dot is 1:(0.95-1.05).

13. The quantum dot composition of claim 9, wherein the first quantum dot satisfies 1.5 eV>ΔE_{CB,S1-C1}, and the second quantum dot satisfies ΔE_{CB,S2-C2}≤0.4 eV and 1.5 eV>ΔE_{VB,C2-S2}.

14. The quantum dot composition of claim 9, wherein the first quantum dot is CdSe/ZnSe, the second quantum dot is CdSe/CdS, a conduction band energy level difference ΔE_{CB, shell-core} of the CdSe/ZnSe is 0.3 eV, a valence band energy level difference ΔE_{VB, core-shell} of the CdSe/ZnSe is 0.5 eV, a conduction band energy level difference ΔE_{CB, shell-core} of the CdSe/ZnSe is 1 eV, a valence band energy level difference ΔE_{VB, core-shell} of the CdSe/ZnSe is 0.1 eV, and a mass ratio of the CdSe/ZnSe to the CdSe/CdS is 1:1.

15. The quantum dot composition of claim 9, wherein the first quantum dot is CdZnSeS/CdZnS/ZnS, the second quantum dot is CdZnSeS/ZnSe/ZnS, a conduction band energy level difference ΔE_{CB, shell-core} of the CdZnSeS/CdZnS/ZnS is 0.2 eV, a valence band energy level difference ΔE_{VB, core-shell} of the CdZnSeS/CdZnS/ZnS is 0.7 eV, a conduction band energy level difference ΔE_{CB, shell-core} of the CdZnSeS/ZnSe/ZnS is 0.8 eV, a valence band energy level difference ΔE_{VB, core-shell} of the CdZnSeS/ZnSe/ZnS is 0.15 eV, and a mass ratio of the CdZnSeS/CdZnS/ZnS to the CdZnSeS/ZnSe/ZnS is 3:1.

16. A quantum dot light-emitting device comprising:
an anode, a hole transport layer, a quantum dot light-emitting layer, and a cathode, which are sequentially stacked;
wherein the quantum dot light-emitting layer comprises the quantum dot composition comprising a first quantum dot and a second quantum dot, the first quantum dot and the second quantum dot are both core-shell quantum dots;
a ratio of a conduction band energy level of a core of the first quantum dot to a conduction band energy level of a core of the second quantum dot is 1:(0.9-1.1), and a ratio of a valence band energy level of the core of the first quantum dot to a valence band energy level of the core of the second quantum dot is 1:(0.9-1.1); or a ratio of a band gap width of a core of the first quantum dot to a band gap width of a core of the second quantum dot is 1:(0.9-1.1);
a conduction band energy level of an outermost shell of the second quantum dot is lower than a conduction band energy level of an outermost shell of the first quantum dot, and a valence band energy level of the outermost shell of the second quantum dot is lower than a valence band energy level of the outermost shell of the first quantum dot;
wherein the first quantum dot satisfies 0<ΔE_{VB,C1-S1}≤0.4 eV and ΔE_{CB,S1-C1}>0.4 eV, and the second quantum dot satisfies 0<ΔE_{CB,S2-C2}<0.4 eV and ΔE_{VB,C2-S2}>0.4 eV;
ΔE_{VB,C1-S1}=E_{VB,C1}−E_{VB,S1}, ΔE_{CB,S1-C1}=E_{CB,S1}−E_{CB,C1}, ΔE_{VB,C2-S2}=E_{VB,C2}−E_{VB,S2}, ΔE_{CB,S2-C2}=E_{CB,S2}−E_{CB,C2}, where C1, S1, C2, and S2 respectively represent the core and the shell of the first quantum dot and the core and the shell of the second quantum dot.

17. The quantum dot light-emitting device of claim 16, wherein a valence band energy level difference between the outermost shell of the first quantum dot and the hole transport layer satisfies ΔE_{HTL-S1}=E_{LUMO,HTL}−E_{VB,S1}<0.5 eV, and a conduction band energy level difference between the outermost shell of the second quantum dot and the electron transport layer satisfies ΔE_{EML-ETL}=E_{CB,S2}−E_{HOMO,ETL}<0.4 eV.

18. The quantum dot light-emitting device of claim 16, wherein the anode and the cathode are independently selected from a doped metal oxide particle electrode, a composite electrode, a graphene electrode, a carbon nanotube electrode, a metal element electrode, or an alloy electrode, the doped metal oxide particle electrode is selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide; the composite electrode is selected from AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, or ZnS/Al/ZnS; and the metal electrode is selected from one or more of Ag, Al, Cu, Au, Mo, Pt, Ca, and Ba;
the quantum dot light-emitting device further comprises an electron transport layer, the electron transport layer is disposed between the quantum dot light-emitting layer and the cathode, and a material of the electron transport layer is selected from one or more of a metal oxide, a doped metal oxide, a group 2-6 semiconductor material, a group 3-5 semiconductor material, and a group 1-3-6 semiconductor material, the metal oxide is selected from one or more of ZnO, BaO, TiO₂, SnO₂; a metal oxide of the doped metal oxide is selected from one or more of ZnO, TiO₂, and SnO₂, and a doping element of the doped metal oxide is selected from one or more of Al, Mg, Li, In, and Ga; the group 2-6 semiconductor material is selected from one or more of ZnS, ZnSe, and CdS; the group 3-5 semiconductor material is selected from one or more of InP and GaP; and the group 1-3-6 semiconductor material is selected from one or more of CuInS and CuGaS;
a material of the hole transport layer is selected from one or more of 4,4′-N,N′-dicarbazolyl-biphenyl (CBP), N,N′-diphenyl-N,N′-bis(1-naphthyl)-1,1′-biphenyl-4,4″-diamine, N,N′-diphenyl-N,N′-bis(3-methylphenyl)-(1,1′-biphenyl)-4,4′-diamine, N,N′-bis(3-methylphenyl)-N,N′-bis(phenyl)-spiro(spire TPD), N,N′-di(4-(N,N′-diphenyl-amino)phenyl)-N,N′-diphenylbenzidine, 4,4′,4′-tris(N-carbazolyl)-triphenylamine, 4,4′,4′-tris(N-3-methylphenyl-N-phenylamino)triphenylamine, poly[(9,9′-dioctylfluorene-2,7-diyl)-co-(4,4′-(N-(4-sec-butyphenyl)diphenylamine))], poly(4-butylphenyl-diphenylamine), polyaniline, polypyrrole, poly(p) phenylenevinylene, poly(phenylenevinylene), poly[2-methoxy-5-(2-ethylhexyloxy)-1,4-phenylenevinylene] and poly[2-methoxy-5-(3′,7′-dimethyloctyloxy)-1,4-phenylenevinylene], copper phthalocyanine, aromatic tertiary amines, polynuclear aromatic tertiary amines, 4,4′-bis(N-carbazolyl)-1,l′-biphenyl compounds, N,N,N′,N′-tetraarylbiphenylamines, PEDOT:PSS and derivatives thereof, poly(N-vinylcarbazole) [(PVK)] and derivatives thereof, polymethacrylates and derivatives thereof, poly(9,9-octylfluorene) and derivatives thereof, poly(spirofluorene) and derivatives thereof, N,N′-di(naphthalen-1-yl)-N,N′-diphenylbenzidine, spiro-NPB, doped graphene, non-doped graphene, C60, doped or non-doped NiO, doped or non-doped MoO₃, doped or non-doped WO₃, doped or non-doped V₂O₅, doped or non-doped P-type gallium nitride, doped or non-doped CrO₃, and doped or non-doped CuO;
the quantum dot light-emitting device further comprises a hole injection layer, the hole injection layer is disposed between the anode and the hole transport layer, and a material of the hole injection layer is selected from one or more of 2,3,6,7,10,11-hexacyano-1,4,5,8,9,12-hexaazatriphenylene, PEDOT, PEDOT:PSS, derivatives of PEDOT:PSS doped with s-MoO₃, 4,4′,4′-tris(N-3-methylphenyl-N-phenylamino)triphenylamine, tetracyanoquinodimethane, copper phthalocyanine, nickel oxide, molybdenum oxide, tungsten oxide, vanadium oxide, molybdenum sulfide, tungsten sulfide, and copper oxide.

19-20. (canceled)

21. The quantum dot light-emitting device of claim 16, wherein a difference between the full width half maximum of the emission spectra of the first quantum dot and a full width at half maximum of the emission spectra of the second quantum dot ranges from 0 nm to 5 nm.

22. The quantum dot light-emitting device of claim 16, wherein the conduction band energy level of the core of the first quantum dot is not more than 10% different from the conduction band energy level of the core of the second quantum dot, and the valence band energy level of the core of the first quantum dot is not more than 10% different from the valence band energy level of the core of the second quantum dot.
